(19) United States
(12) Patent Application Publication
(10) Pub. No.: US 2014/0373921 A1
(43) Pub. Date: Dec. 25, 2014

(54) METHOD FOR RE-DYEING DYE SENSITISED SOLAR CELLS

(71) Applicant: BANGOR UNIVERSITY, Bangor, GW (GB)

(72) Inventors: Peter James Holliman, Conwy (GB); Kareem Jumaah Jibrael Al-Salahi, Bangor (GB); Matthew Davies, Bangor (GB)

(73) Assignee: BANGOR UNIVERSITY, Bangor (GB)

(21) Appl. No.: 14/374,629

(22) PCT Filed: Jan. 25, 2013
(86) PCT No.: PCT/GB2013/050171

§ 371 Date: Jul. 25, 2014

(30) Foreign Application Priority Data
Jan. 26, 2012 (GB) 1201336.3
Mar. 30, 2012 (GB) 1205676.8
Aug. 5, 2012 (GB) 1213893.9

(51) Int. Cl. H01G 9/20; H01L 51/00

(52) U.S. Cl. CPC H01G 9/2031; H01G 9/2059; H01L 51/0003
USPC 136/263; 438/82

(57) ABSTRACT

The present invention relates to the field of dye sensitised solar cells and discloses a method for multiple desensitising and re-dyeing, including partial desensitisation and multiple re-dyeing with single or mixed dyes.

### FIELD OF THE INVENTION

The present invention relates to the field of dye sensitised solar cells and discloses a method for multiple desensitising and re-dyeing.

### BRIEF DESCRIPTION OF THE RELATED ART

Dye-sensitised solar cells (DSSC) have been developed in 1991 by O'Regan and Grätzel (O'Regan B. and Grätzel M., in Nature, 1991, 353, 737-740). They are produced with low cost material and do not require complex equipment for their manufacture. They separate the two functions provided by silicon: the bulk of the semiconductor is used for charge transport and the photoelectrons originate from a separate photosensitive dye. The cells are sandwich structures.

In these cells, photons strike the dye moving it to an excited state capable of injecting electrons into the conducting hand of the titanium dioxide from where they diffuse to the anode. The electrons lost from the dye/TiO₂ system are replaced by oxidising the iodide into triiodide at the counter electrode, which reaction is sufficiently fast to enable the photochemical cycle to continue.

The DSSC generate a maximum voltage comparable to that of the silicon solar cells, of the order of 0.8 V. An important advantage of the DSSC as compared to the silicon solar cells is that the dye molecules injects electrons into the titanium dioxide conduction band creating excited state dye molecules rather than electron vacancies in a nearby solid, thereby reducing quick electron/hole recombinations. They are therefore able to function in low light conditions where the electron/hole recombination becomes the dominant mechanism in the silicon solar cells. The present DSSC are however not very efficient in the longer wavelength part of the visible light frequency range, in the red and infrared region, because these photons do not have enough energy to cross the titanium dioxide band-gap or to excite most traditional ruthenium bipyridyl dyes.

In order to absorb as broad a spectrum of photons of different wavelengths across the visible region as possible, there are several options. In the prior art, dyes having a broad absorption spectrum have been used. For instance, the ruthenium terpyridyl dye commonly known as “black dye” absorbs light up to a wavelength of 900 nm(M. K. Nazeeruddin, P. Péchy and M. Grätzel, Chem. Commun., 1997, pages 1705-1706). Such dyes however have a moderate absorption coefficient across the broad range of wavelengths. Another option is to use more than one dye to absorb photons in different parts of the solar spectrum. This can be achieved by building different ‘sandwiched’ solar cells, each having a performing dye in a narrow wavelength band, and stacking them. These stacked cells however have a bigger thickness than simple cells and are therefore less transparent. This can also be achieved by adding both dyes within a single titania photo-electrode thereby forming “cocktail” dyeing. This latter method is however very difficult to achieve in practice because of the need to match the current, the electrolyte and the dye uptake of the different dyes. The few successful attempts to achieve multiple dyeing of a single photo-electrode have required slow dyeing procedures as disclosed for example in Cid et al. (J-J. Cid, J-H. Yum, S-R. Jang, M. K. Nazeeruddin, E. Martinez-Ferrero, E. Palomares, J. Ko, M. Grätzel and T. Torres, Angewandte Chemie International Edition, 2007, 46, 8358-8362) and in Kuang et al. (D. Kuang, P. Walter, F. Nüesch, S. Kim, J. Ko, P. Comte, S. K. Zakeeruddin, M. K. Nazeeruddin and M. Grätzel, Langmuir, 2007, 23, 10906-10909) and/or have used pressure such as supercritical carbon dioxide as disclosed in Inakazu et al. (F. Inakazu, Y. Noma, Y. Ogomi and S. Hayase, Applied Physics Letter, 2008, 93, 093304-1 to 093304-3) or two-phase photo-electrodes as disclosed in Lee et al. (K. Lee, S. Woong Park, M. Jae Ko, K. Kim) and in Park (N. Park, Nature Materials, 2009, 8, 665-671) to selectively dye different parts of the photo-electrode.

A lot of effort has been spent to increase the speed of dyeing as disclosed for example In WO2010/089263, or to improve the use of multiple dyes as disclosed for example in WO2011/154473.

There is however still a need to prepare robust solar cells that can be prepared rapidly and have an efficient and controlled photon absorption over a broad wavelength range.

### LIST OF FIGURES

FIG. 1 represents a dye sensitised solar cell suitable for use in the present invention, characterised in that the dye solutions are introduced between sealed electrodes wherein the counter-electrode has been pierced with two-holes, one for pumping in the dye solutions or desensitiser solution and the other for collecting excess liquid.

FIG. 2 represents the UV-visible spectra of selectively desorbed N719, SQ1 and D149.

### SUMMARY OF THE INVENTION

It is an objective of the present invention to prepare dye sensitised solar cells which can harvest photons across s broad range of wavelengths.

It is also an objective of the present invention to control the amount of different dyes deposited on the cell.

It is another objective of the present invention to increase the efficiency of the solar cells.

It is yet another objective of the present invention to use in the same devices dyes that are otherwise incompatible in sensitisation and in operation.

It is a further objective of the present invention to change dyes rapidly.

The foregoing objectives have been carried out as described in the independent claims. Preferred embodiments are disclosed in the dependent claims.

### DETAILED DESCRIPTION OF THE INVENTION

Accordingly, the present invention discloses a method for desorbing dye(s) from a finished dye sensitised solar cell (DSC) and optionally re-dyeing said cell with the same or another or several dye(s) that comprises the steps of:
a) providing a sandwich cell structure comprising an electrode unit and a counter electrode unit, said electrode units being sealed together and comprising two holes drilled in the counter electrode;
b) sensitising the metal oxide photo-electrode by pumping a solution containing one or more dyes and/or a template molecule through the device cavity;
c) desensitising the DSC of step b), either partially or completely, by pumping an alkaline solution between the sealed electrodes through one of the drilled holes and recovering the excess through the second hole, and wherein the alkaline solution has a pK_{b} ranging between −1 and 5 and wherein the reaction products of the dye and the alkaline solution reaction have a pH ranging between 8 and 14;
d) washing the desensitised cavity with solutions comprising either de-ionised water and/or an aqueous acid such a hydrochloric acid and/or organic solvents such as ethanol and/or acetone;
e) optionally pumping between the sealed electrodes, through one of the drilled holes in the counter-electrode, a new dye solution or a mixture of dyes in solution, said one or more dyes solution optionally comprising a template, said pumping being carried out at a rate adapted to the nature of the one or more dyes in solution;
f) optionally filling the re-dyed cell with fresh electrolyte;
g) optionally, recycling the removed one or more dyes;
h) repeating steps b) through f) as many time as desired with the same or different dyes and/or templates.

Preferably, the desensitised solar cells are re-dyed and steps e) and f) are present.

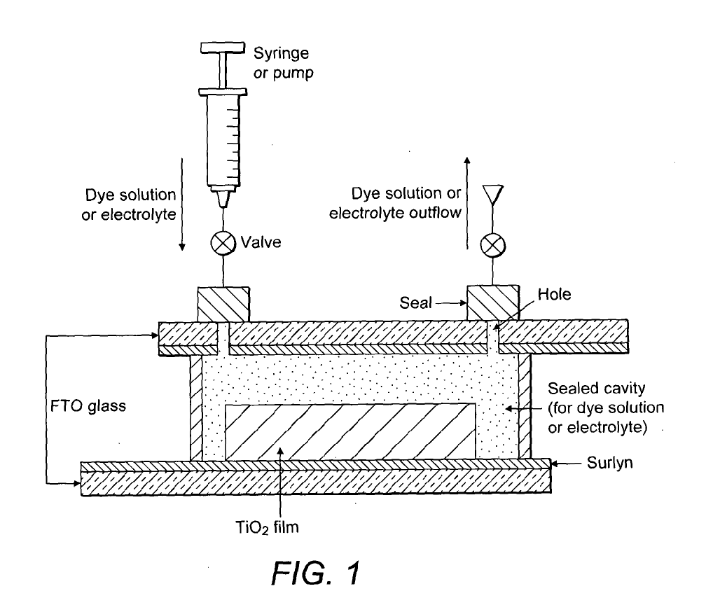

The DSC can be selected from any available cell on the market. In a preferred embodiment according to the present invention, it is prepared following the fast dyeing method disclosed in WO2010/089263. A typical DSC arrangement used in the present invention is represented in FIG. 1. It is characterised in that the dye solutions are introduced between sealed electrodes and wherein the counter-electrode has been pierced with two-holes, one for pumping in the dye solutions or desensitiser solution and the other for collecting excess liquid.

The desensitising step is typically carried out by flowing through one of the holes drilled in the counter electrode, a solution comprising a base X⁺ OH⁻ wherein X is the positive counterion and OH⁻ is the hydroxide ion initially present as hydroxide or as the product of hydrolysis and recovering said solution through the other hole. The base is preferably selected from a solution having a pK_{b} ranging between −1 and 5, more preferably between 0.5 and 4. Suitable bases are listed in Table 1. It can be selected for example from organic amines, ammonium hydroxides or alkaline metal hydroxides including tetra-butyl ammonium hydroxide solution or ammonium hydroxide solution or lithium hydroxide. In addition, the desorption products are typically [X⁺ Dye⁻]+H₂O, which have little or no acidity with a pH ranging between 5 and 9, preferably between 6 and 8. The present method allows recycling of the dye(s). It must be noted that different dyes desorb differently: for example, the red ruthenium-bipyridyl dye commonly known as N719 desorbs more easily than the blue squaraine dye commonly known as SQ1.

TABLE 1

| Base | Formula | pK_{b} |
|---|---|---|
| Lithium hydroxide | LiOH | −0.36 |
| Sodium hydroxide | NaOH | 0.2 |
| Hydroxylamine | NH₂OH | 0.3 |
| Potassium hydroxide | KOH | 0.5 |
| Calcium hydroxide | Ca(OH)₂ | 2.4, 1.4 |
| Ammonium hydroxide | NH₄OH | 4.75 |
| Piperidine | C₅H₁₁N | 2.9 |
| Ethylamine | C₂H₅NH₂ | 3.25 |
| tert-butylamine | C₄H₁₁N | 3.32 |
| Methylamine | CH₃NH₂ | 3.36 |
| Pyridine | C₅H₅N | 5.21 |
| Aniline | C₆H₅NH₂ | 9.4 |

Partial dye removal from the metal oxide surface is achieved by the pK_{b} and counter-ion of the base used, by controlling the concentration of the alkaline solution used, by controlling the temperature at which desensitising process is carried out, by controlling the rate at which the alkaline solution is pumped through the device cavity, by controlling the volume of base solution used, by controlling the contact time of the base solution with the metal oxide within the device cavity and by controlling the nature of the dye on the surface. The latter means that the order of sensitisation and desensitisation is important. The nature of the base used should be chosen to achieve sufficient alkalinity to ensure dye removal from the metal oxide surface whilst also causing minimal change to any other components within the device cavity.

The device cavity is then optionally washed several times with water and/or mild acid and/or alcohol and/or acetone.

It can subsequently be filled with electrolyte in order to verify its performance after dye desorption. The electrolyte can be of various types; a liquid, a gel or a solid. Liquid and gel electrolytes are typically based on a redox couple such as the commonly used iodide/triiodide redox couple dissolved in a liquid such as a nitrile organic solvent selected for example from acetonitrile or methoxypropionitrile. Gel electrolytes are similar but also contain a gelling agent such as a long chain organic polymer. Solid electrolytes can include conducting organic polymer polymers such as PEDOT or spiro-OMETAD or inorganic solid electrolytes such as Cul.

The cell is now ready for re-dyeing with one or more dyes. It has been observed that different dyes are adsorbed in the titanium oxide layer at different speeds depending on the temperature of the process, the nature of the metal oxide, the dye solution solvents used, the rate of pumping of the dye solution through the device cavity and the nature of the dye molecules, dye counterions and co-sorbents present within the dye solution. For example, the blue squaraine dye commonly known as SQ1 is adsorbed much faster than the red ruthenium-bipyridyl dye commonly known as N719 when being sensitised onto titania photo-electrodes from ethanolic solution, examples of the rate constants of adsorption being respectively of the order of 3 cm² ug⁻¹ for the blue dye SQ1 and 4×10⁻³ cm²ug⁻¹ for the red dye N719. Consequently, the rate of deposition of a mixture of dyes determines the efficiency of dye impregnation. If a mixture of red and blue dyes is pumped rapidly into the cell's cavity, the red dye tends to occupy the lower part of the titanium oxide layer whereas the blue dye occupies the upper layer. If the same mixture is pumped slowly through the cavity, the impregnation of red and blue dyes is uniform throughout the titanium oxide layer.

In the prior art DSC comprising a mixture of dyes, the only control was the ratio of dyes and the speed of injection.

The DSC according to the present invention offer additional control. Preselected amounts of dye can be removed from the cell and replaced by controlled amounts of the same or different dyes. In addition, the mixture of dyes can additionally comprise a template. The template consists of bulky, inert molecules which also have a linking group which can coordinate to the metal oxide surface. The linking group can include anionic or cationic compounds such as carboxylates, phosphonates, sulfonates or amines. Examples of template molecules include chenodeoxycholic acid, stearic acid, tertiary butyl pyridine, amino acids or guanadino carboxylic acids. These molecules separate the dye molecules, thereby preventing the recombination process that can occur when the positively charged dye ions are too close to one another and can thus recapture the emitted electrons.

It is highly desirable to use a combination of dyes in order to cover a large fraction of the visible light and near infra-red, Ideally between 400 and 1200 nm. For that purpose, several dyes need to be used. A photon of light absorbed by the dye promotes an electron into one of its excited states. This excited electron is in turn injected into the conduction band of the metal oxide. The dye must also have the capability to be subsequently reduced by a redox couple present In the electrolyte. Suitable dyes can be selected from ruthenium bipyridyl complexes, ruthenium terpyridyl complexes, coumarins, phthalocyanines, squaraines, indolines or triarylamine dyes.

It is known however that different dyes may not have compatible serialisations and/or compatible modes of operation. The method according to the present invention, using partial dye removal, re-dying and templates, allows a very accurate control of the amount of each dye present in the metal oxide layer.

When dye solutions are sequentially introduced between sealed electrodes, it is observed that the resulting efficiency of the cell is higher than that of each separate dye. It is also more efficient than a single broad band dye as the absorption of each separate dye is characterised by a narrow and intense absorption peak.

The dye removal and re-dyeing operations can be repeated as many times as desired without degrading the efficiency of the DSC.

The dyes are preferably recycled. This is achieved by recovering the desensitised dye solution from the device cavity by pumping and then neutralising any excess alkalinity with acid. The dye solution is then ready to re-dye other devices.

The present invention thus discloses a very efficient method for introducing in the DSC, in a totally compatible and controlled manner, a large number dyes, each efficiently absorbing light in specific portion of the visible or near-infrared part of the spectrum.

### EXAMPLES

### Example 1

### Dyeing, Desensitising and Re-Dyeing with the Same Dye in the Near Infrared (NIR) Region of the Spectrum

The TiO₂electrode of a sealed DSC device was dyed with the NIR dye SQ1 by pumping dye solution (0.28 mM) through the device cavity at a flow rate of 200 μL min⁻¹ for 10 minutes. After the device performance had been measured as reported in Table 2, the SQ1 dye was deserted using a tertiary-butyl ammonium hydroxide solution (1% by weight prepared by dissolving 1 g of tertiary-butyl ammonium hydroxide in 100 ml of a 50:50 vol/vol ethanol:water solution). The device cavity was then washed sequentially with de-ionised water, 0.1 M HCl_{(aq)}, de-ionised water, ethanol and acetone and then filled with I₃⁻/I⁻ electrolyte. The device performance was re-measured and the efficiency was found to have dropped significantly confirming dye removal as reported in Table 2. Finally the electrolyte was removed from the device cavity which was again rinsed with de-ionised water, 0.1 M HCl_{(aq)}, de-ionised water, ethanol and acetone in the same manner as described above and the same device was re-dyed with SQ1 and fresh electrolyte was added; the resulting device performance is shown In Table 2.

TABLE 2

| Device | η (%) | V_{OC} (V) | J_{SC} (mA/cm²) | FF |
|---|---|---|---|---|
| Initial dye | 1.3 | 0.64 | 3.03 | 0.68 |
| Desensitised | 0.3 | 0.64 | 0.78 | 0.60 |
| Re-dyed | 1.7 | 0.64 | 4.54 | 0.57 |

### Example 2

### Dyeing, Desensitising and Re-Dyeing with the Same Dye

The TiO₂ electrode of a sealed DSC device was dyed with the Ru-bipy dye N719 (Dyesol) by pumping dye solution (2.8 mM) through the device cavity at a flow rate of 200 μL min⁻¹ for 10 minutes. After the device performance had been measured as reported in Table 3, the N719 dye was desorbed using a tertiary-butyl ammonium hydroxide solution (1% by weight prepared by dissolving 1 g of tertiary-butyl ammonium hydroxide in 100 ml of a 50:50 vol/vol ethanol:water solution). The device cavity was then washed sequentially with de-ionised water, 0.1 M HCl_{(aq)}, water, ethanol and acetone and then filled with I₃⁻/I⁻ electrolyte. The device performance was re-measured and the efficiency was found to have dropped significantly confirming dye removal. Finally the electrolyte was removed from the device cavity which was again rinsed with de-ionised water, 0.1 M HCl_{(aq)}, de-ionised water, ethanol and acetone in the same manner as described above and the same device was re-dyed with N719 (2.8 mM) and fresh electrolyte was added. The desorption and re-dyeing cycle was then repeated using the same procedure and showing the same trends in device efficiency. The desensitised and re-dyed device's characteristics are also reported in Table 3.

TABLE 3

| Device | η (%) | V_{OC} (V) | J_{SC} (mA/cm²) | FF |
|---|---|---|---|---|
| Initial dye | 4.5 | 0.78 | 11.06 | 0.52 |
| 1^{st} desensitised | 0.3 | 0.58 | 0.95 | 0.64 |
| 1^{st} re-dyed | 4.5 | 0.77 | 10.96 | 0.53 |
| 2^{nd} desensitised | 0.4 | 0.60 | 0.98 | 0.65 |
| 2^{nd} re-dyed | 3.7 | 0.76 | 12.20 | 0.40 |

### Example 3

### Dyeing, Desensitising and Re-Dyeing with Another Dye

A sealed TiO₂ photo-electrode was dyed with the NIR dye SQ1 using the fast dyeing technique described above. After the device performance had been measured as reported in Table 4, the SQ1 dye was desorbed using tertiary-butyl ammonium hydroxide solution (1% by weight in 50:50 ethanol-water solution). Finally the same device was re-dyed with N719 and fresh electrolyte was added. The re-dyed device's characteristics are also reported in Table 4.

TABLE 4

| Device | Dye | η (%) | V_{OC} (V) | J_{SC} (mA/cm²) | FF |
|---|---|---|---|---|---|
| 1st dye | SQ1 | 1.6 | 0.65 | 3.70 | 0.68 |
| 2^{nd} dye | N719 | 4.0 | 0.77 | 9.79 | 0.53 |

### Example 4

### Dyeing, Desensitising and Re-Dyeing with Another Dye

A sealed TiO₂ photo-electrode was dyed with the Ru-bipy dye N719 using the fast dyeing technique described above and this was labelled Device D. After the device performance had been measured as reported in Table 5, the N719 dye was desorbed using aqueous tertiary-butyl ammonium hydroxide solution (1% by weight in 50:50 ethanol-water solution). Finally the same device was re-dyed with the NIR dye SQ1 and fresh electrolyte was added. The re-dyed device's characteristics are also reported in Table 5.

TABLE 5

| Device | Dye | η (%) | V_{oc} (V) | J_{sc} (mA/cm²) | FF |
|---|---|---|---|---|---|
| 1st dye | N719 | 4.4 | 0.79 | 11.05 | 0.50 |
| 2^{nd} dye | SQ1 | 1.9 | 0.64 | 4.61 | 0.64 |

### Example 5

### Re-Dyeing the Ru-Terpyridyl Dye—“Black Dye”

The TiO₂ electrode of a sealed DSC device was dyed with the Ru-terpyridyl dye “Black dye” (1 mM) by pumping dye solution through the device cavity at a flow rate of 200 μL min⁻¹ for 10 minutes, After the device performance had been measured as reported in Table 8, the “Black dye” dye was desorbed using tertiary-butyl ammonium hydroxide solution (1% by weight in 50:50 ethanol-water solution). The device cavity was then washed sequentially with de-ionised water, 0.1 M HCl_{(aq)}, de-ionised water, ethanol and acetone and then filled with electrolyte. The device performance was re-measured and the efficiency was found to have dropped significantly confirming dye removal. Finally the electrolyte was removed from the device cavity which was again rinsed with de-ionised water, 0.1 M HCl_{(aq)}, de-ionised water, ethanol and acetone in the same manner as described above and the same device was re-dyed with “Black dye” (1 mM) and fresh electrolyte was added. The desorption and re-dyeing cycle was then repeated using the same procedure and showing the same trends in device efficiency. The desensitised and re-dyed device's characteristics are also reported in Table 6.

TABLE 6

| Device | η (%) | V_{oc} (V) | J_{sc} (mA cm⁻²) | FF |
|---|---|---|---|---|
| Initial dye | 2.2 | 0.66 | 5.08 | 0.65 |
| 1^{st} desensitised | 0.3 | 0.57 | 0.74 | 0.63 |
| 1^{st} re-dyed | 2.2 | 0.68 | 5.23 | 0.62 |
| 2^{nd} desensitised | 0.2 | 0.56 | 0.74 | 0.57 |
| 2^{nd} re-dyed | 2.0 | 0.66 | 4.99 | 0.61 |

### Example 6

### Re-Dyeing the Organic Dye D149

The TiO₂ electrode of a sealed DSC device was dyed with the organic dye D149 (0.5 mM, Innabata) by pumping dye solution through the device cavity at a How rate of 200 μL min⁻¹ for 10 minutes. After the device performance had been measured as reported in Table 7, the D149 dye was desorbed using aqueous tertiary-butyl ammonium hydroxide solution (1% by weight in 50:50 ethanol-water solution). The device cavity was then washed sequentially with de-ionised water, 0.1 M HCl_{(aq)}, de-ionised water, ethanol and acetone and then filled with electrolyte. The device performance was re-measured and the efficiency was found to have dropped significantly confirming dye removal. Finally the electrolyte was removed from the device cavity which was again rinsed with de-ionised water, 0.1 M HCl_{(aq)}, de-ionised water, ethanol and acetone in the same manner as described above and the same device was re-dyed with D149 (0.5 mM, Innabata) and fresh electrolyte was added. The desensitised and re-dyed device's characteristics are also reported in Table 7.

TABLE 7

| Device | η (%) | V_{oc} (V) | J_{sc} (mA cm⁻²) | FF |
|---|---|---|---|---|
| First dyeing | 4.0 | 0.76 | 10.67 | 0.50 |
| After dye | 0.4 | 0.61 | 1.11 | 0.65 |
| desorption | | | | |
| Re-dyed | 3.5 | 0.75 | 10.62 | 0.44 |

### Example 7

### Re-Dying a Co-Sensitised Device

A mixed dye solution containing N719 and SQ1 was prepared by mixing 4300 μL of N718 solution (2 mM) with 700 μL of SQ1 solution (0.4 mM) to give an overall ratio N719:SQ1 of 98.5%:1.5% (conc. to conc.). The TiO₂ electrode of a sealed DSC device was then dyed by pumping this mixed N719:SQ1 dye solution through the device cavity at a flow rate of 200 μL min⁻¹ for 10 minutes. After the device performance had been measured as reported in Table 8, the dyes were desorbed using aqueous tertiary-butyl ammonium hydroxide solution (1% by weight in 50:50 ethanol-water solution). The device cavity was then washed sequentially with de-ionised water, 0.1 M HCl_{(aq)}, de-ionised water, ethanol and acetone and then filled with electrolyte. The device performance was re-measured and the efficiency was found to have dropped significantly confirming dye removal. The concentration of N719 dye desorbed from the TiO₂ photo-electrode was also measured using UV-visible spectroscopy and the data are shown in Table 8. Finally the electrolyte was removed from the device cavity which was again rinsed with de-ionised water, 0.1 M HCl_{(aq)}, de-ionised water, ethanol and acetone in the same manner as described above and the same device was re-dyed with mixed N719:SQ1 dye solution wherein the 2 dyes were in the same ratio as that of the initial mixed dye solution and fresh electrolyte was added. The desensitised and re-dyed device's characteristics are also reported in Table 8.

TABLE 8

| | η | V_{oc} | J_{sc} | | N719 (μg | SQ1 |
|---|---|---|---|---|---|---|
| Device | (%) | (V) | (mA cm⁻²) | FF | cm⁻²) | (μg cm⁻²) |
| Dyed with | 5.0 | 0.78 | 10.23 | 0.63 | 240 | 1 |
| N719/SQ1 | | | | | | |
| After | 0.3 | 0.59 | 0.78 | 0.63 | — | — |
| desorption | | | | | | |
| of all dyes | | | | | | |
| Re-dyed | 5.0 | 0.80 | 10.33 | 0.61 | 202 | 1 |
| with N719/ | | | | | | |
| SQ1 | | | | | | |

### Example 8

### Partially Removal of N719 Dye and Then Re-Dyeing with Different Dyes

The TiO₂ electrode of a sealed DSC device was dyed with N719 by pumping dye solution (2.8 mM) through the device cavity at a flow rate of 200 μL min⁻¹ for 10 minutes. After the device performance had been measured as reported in Table 9, the N719 dye was partially desorbed using aqueous tertiary-butyl ammonium hydroxide solution (0.001% by weight in 50:50 ethanol-water solution). The device cavity was then washed sequentially with de-ionised water, 0.1 M HCl_{(aq)}, de-ionised water, ethanol and acetone and then filled with electrolyte. The device performance was re-measured and the efficiency was found to have dropped slightly confirming partial dye removal as reported in table 9. The electrolyte was then removed from the device cavity which was again rinsed with de-ionised water, 0.1 M HCl_{(aq)}, de-ionised water, ethanol and acetone and the same device was re-dyed with SQ1 (0.28 mM) and fresh electrolyte was added. The electrolyte was then removed from the device cavity which was again rinsed with de-ionised water, 0.1 M HCl_{(aq)}, de-ionised water, ethanol and acetone in the same manner as described above and the same device was re-dyed with N719 (2.8 mM) and fresh electrolyte was added. The partially desensitised and re-dyed device's characteristics are also reported in Table 9.

TABLE 9

| Device | η (%) | V_{oc} (V) | J_{sc} (mA cm⁻²) | FF |
|---|---|---|---|---|
| Dyed with N719 | 4.7 | 0.80 | 9.41 | 0.62 |
| Partial removal of N719 | 4.1 | 0.78 | 7.82 | 0.68 |
| After partial N719 removal, | 3.5 | 0.71 | 7.34 | 0.67 |
| re-dye with SQ1 | | | | |
| after dyed with SQ1, then | 4.1 | 0.74 | 9.05 | 0.61 |
| re-dyed with N719 | | | | |

### Example 9

### Examples Showing Repeated Partial Desorption and Re-Dyeing with Different Dyes

The TiO₂ electrode of a sealed DSC device was dyed with N719 by pumping dye solution (2.8 mM) through the device cavity at a flow rate of 200 μL min⁻¹ for 10 minutes followed by I₃⁻/I⁻ electrolyte and this was labelled Device J-A. After the device performance had been measured as reported in Table 10, all the N719 dye was desorbed (185 μg cm⁻²) using aqueous tertiary-butyl ammonium hydroxide solution (1% by weight in 50:50 ethanol-water solution). The device cavity was then washed sequentially with de-ionised water, 0.1 M HCl_{(aq)}, de-ionised water, ethanol and acetone and then re-filled with electrolyte. This device was labelled Device J-A1 and the performance was re-measured and the efficiency was found to have dropped significantly confirming N719 dye removal as reported in Table 10. The electrolyte was then removed from the device cavity which was again rinsed with de-ionised water, 0.1 M HCl_{(aq)}, de-ionised water, ethanol and acetone in the same manner as described above. The same device was re-dyed with N719 (2.8 mM) and then N719 partially removed using 20 μl of tertiary-butyl ammonium hydroxide solution before fresh electrolyte was added; the resulting device was labelled J-A1-P. The electrolyte was then removed from the device cavity which was again rinsed with de-ionised water, 0.1 M HCl_{(aq)}, de-ionised water, ethanol and acetone in the same manner as described above and the same device was re-dyed with SQ1 (0.24 mg I⁻¹) and fresh electrolyte was added. The resulting device was labelled J-A1-R. All the dyes were then removed using TBN showing 30 of N719 and 13 of SQ1; fresh electrolyte was added and the device performance of Device J-A2 had dropped significantly reflecting complete dye removal as reported in Table 10. The dyeing and dye desorption cycles were then repeated on the same device to show re-dyeing with N719 (Device J-B), partial removal of N719 (Device J-B1-P), re-dyeing with SQ1 to dye surface sites vacated by N719 (Device J-B1-R) and complete dye removal (Device J-B2). The final set of devices show that the metal oxide can again be re-dyed with N719 (Device J-C), that the N719 dye can again be partially removed (Device J-C1-P) and re-dyed again with N719 (Device J-C2-R). This shows that the device can repeatedly be dyed, the dye removed and then re-dyed. All results are summarised in Table 10.

TABLE 10

| | | | | | | Desorbed | Desorbed |
|---|---|---|---|---|---|---|---|
| | | η | V_{oc} | J_{sc} | | N719 | SQ1 |
| Device | | (%) | (V) | (mA cm⁻²) | FF | (μg cm⁻²) | (μg cm⁻²) |
| J-A | First dyed with | 5.0 | 0.77 | 10.64 | 0.61 | 185 | 0 |
| | N719 | | | | | | |
| J-A1 | After desorption | 0.3 | 0.58 | 0.74 | 0.65 | 0 | 0 |
| | of all dye | | | | | | |
| J-A1-P | N719 re-dyed, | 4.5 | 0.79 | 11.21 | 0.51 | 116 | 0 |
| | then partial | | | | | | |
| | removal | | | | | | |
| J-A1-R | SQ1 added | 1.5 | 0.65 | 3.28 | 0.72 | 30 | 13 |
| J-A2 | After desorption | 0.3 | 0.59 | 0.69 | 0.65 | — | — |
| | of all dyes | | | | | | |
| J-B | Re-dyed with | 4.5 | 0.77 | 11.27 | 0.52 | — | — |
| | N719 | | | | | | |
| J-B1-P | After partial | 3.8 | 0.70 | 8.08 | 0.67 | 79 | 0 |
| | N719 removal | | | | | | |
| J-B1-R | SQ1 added | 4.0 | 0.68 | 9.82 | 0.59 | 95 | 22 |
| J-B2 | After desorption | 0.3 | 0.57 | 0.74 | 0.63 | — | — |
| | of all dyes | | | | | | |
| J-C | Re-dyed with | 4.6 | 0.76 | 12.31 | 0.49 | — | — |
| | N719 | | | | | | |
| J-C1-P | After partial | 4.0 | 0.70 | 8.72 | 0.66 | 104 | — |
| | N719 removal | | | | | | |
| J-C2-R | Re-dyed with | 4.7 | 0.75 | 11.77 | 0.53 | 225 | — |
| | N719 | | | | | | |

### Example 10

### Dyeing with D149, Desensitising and Re-Dyeing with a Mixed N719-D149 Dye Solution

The TiO₂ electrode of a sealed DSC device was dyed with the indoline dye D149 (Mitsubishi) by pumping dye solution (0.5 mM) through the device cavity at a flow rate of 200 μL min⁻¹ for 10 minutes. After the device performance had been measured as reported in Table 11, the D149 dye was desorbed using a tertiary-butyl ammonium hydroxide solution (1% by weight prepared by dissolving 1 g of tertiary-butyl ammonium hydroxide in 100 ml of a 50:50 vol/vol ethanol:water solution). The device cavity was then washed sequentially with de-ionised water, 0.1 M HCl_{(aq)}, de-ionised water, ethanol and acetone and then filled with I₃⁻/I⁻ electrolyte. The device performance was re-measured and the efficiency was found to have dropped significantly confirming dye removal. The electrolyte was removed from the device cavity which was again rinsed with de-ionised water, 0.1 M HCl_{(aq)}, de-ionised water, ethanol and acetone in the same manner as described above and the same device was re-dyed and fresh electrolyte was added. In this case, a mixed dye solution containing N719 and D149 was prepared in tertiary-butanol:acetonitrile (1:1 v/v) by mixing 1 ml of a stock solution of N719 (2.8 mM) with 1 ml of a stock solution of D149 (0.5 mM). The re-dyed device's characteristics are also reported in Table 11.

TABLE 11

| Device | η (%) | V_{oc}(V) | J_{sc}(mA cm⁻²) | FF |
|---|---|---|---|---|
| Dyed with D149 | 5.0 | 0.69 | 12.74 | 0.57 |
| Dye desorbed and re-dyed | 5.5 | 0.75 | 12.16 | 0.60 |
| with N719-D149 mix | | | | |

### Example 11

### Dyeing with a Mixed N719-D149 Dye Solution, Desensitising and Re-Dyeing with D149, Desensitising and Re-Dyeing with N719, Desensitising and Re-Dyeing with a Mixed N719-D149 Dye Solution

A mixed dye solution containing N719 and D149 was prepared in tertiary-butanol:acetonitrile (1:1 v/v) by mixing 1 ml of a stock solution of N719 (2.8 mM) with 1 ml of a stock solution of D149 (0.5 mM). The TiO₂ electrode of a sealed DSC device was dyed with this mixed N719-D149 dye solution through the device cavity at a flow rate of 200 μL min⁻¹ for 10 minutes. It was labelled L.-A. After the device performance had been measured as reported in Table 12, the dyes were desorbed using a solution of tertiary-butyl ammonium hydroxide solution (1% by weight prepared by dissolving 1 g of tertiary-butyl ammonium hydroxide in 100 ml of a 50:50 vol/vol ethanol:water solution). The device cavity was then washed sequentially with de-ionised water, 0.1 M HCl_{(aq)}, de-ionised water, ethanol and acetone and then filled with I₃⁻/I⁻ electrolyte. The device was labelled L-A1, its performance was re-measured and the efficiency was found to have dropped significantly confirming dye removal. The electrolyte was removed from the device cavity which was again rinsed with de-ionised water, 0.1 M HCl_{(aq)}, de-ionised water, ethanol and acetone in the same manner as described above and the same device was re-dyed with D149 (0.5 mM, Mitsubishi) and fresh electrolyte was added. The re-dyed device was labelled L-A1-RD, its characteristics are reported in Table 12. The dye was removed and the device cavity washed as described above. Electrolyte was added and the device efficiency had dropped, it was labelled L-B1. The device cavity was washed again as described above and the device was re-dyed with N719 (2.8 mM, Dyesol). It was labelled L-B1-RN. The de-sensitisation and washing cycle was repeated and the device was labelled L-C1. It was then re-dyed with a mixed N719-D149 solution and was labelled L-C1-RM. All results are reported in Table 12.

TABLE 12

| | | | | J_{sc} | |
|---|---|---|---|---|---|
| Device | | η (%) | V_{oc}(V) | (mA/cm²) | FF |
| L-A | Dyed with N719-D149 | 5.4 | 0.8 | 10.81 | 0.63 |
| L-A1 | Dye desorption | 0.3 | 0.56 | 0.83 | 0.62 |
| L-A1-RD | Re-dye with D149 | 4.8 | 0.64 | 13.22 | 0.57 |
| L-B1 | Dye desorption | 0.3 | 0.57 | 0.84 | 0.62 |
| L-B1-RN | Re-dye with N719 | 4.5 | 0.78 | 9.69 | 0.60 |
| L-C1 | Dye desorption | 0.3 | 0.55 | 0.84 | 0.61 |
| L-C1-RM | Re-dyed with | 5.3 | 0.75 | 12.24 | 0.58 |
| | N179-D149 | | | | |

### Example 12

A TEC® (TEC is the trademark for fluoride-doped tin oxide (FTO) coated glass manufactured by NSG) glass device was prepared with a P25 TiO₂ colloid sintered onto the photo-electrode and Pt sintered on to the counter electrode. The two electrodes were then sealed together with a Surlyn gasket and the device photo-electrode was then sequentially dyed with N719 solution (1 mM), then dye was partially desorbed using tertiary-butyl ammonium hydroxide (100 μl, 2 mM) and the device cavity was rinsed as described previously before re-dyeing with a solution of 3-[(1-ethyl-1,3-dihydro-3,3-dimethyl-2H-indol-2-ylidene)methyl]-4-hydroxy-cyclobutene-1,2-dione otherwise known as half SQ1 (HfSQ1) dye. Dye was then completely removed and the device cavity rinsed before re-dyeing with N719. Dye sorption, desorption and rinsing steps were then repeated on the same device and the dyes/procedures used and the resulting I-V test data are described in Table 13. The SQ1 solutions also contained 5 mM chenodeoxycholic acid (CDCA) and the mixed half SQ1 and SQ1 solution was prepared in 1:1 v/v ratio (1 ml of 0.68 mM SQ1 and 1 ml of 0.1 mM HfSQ1). These data show that it is possible to carry out partial desorption of N719 and then to re-dye the same photo-electrode with a different dye.

TABLE 13

| | | | | I_{sc} | |
|---|---|---|---|---|---|
| Device | | η % | V_{oc}/V | mA/cm² | FF |
| M-A | Dyed with N719 | 4.3 | 0.79 | 8.60 | 0.64 |
| M-B | Removal of ca. 60% N719 | 2.1 | 0.72 | 4.13 | 0.70 |
| M-C | Re-dyed with half SQ1 | 3.2 | 0.69 | 7.14 | 0.66 |
| M-D | After desorption of all dye | 0.3 | 0.61 | 0.77 | 0.67 |
| M-E | Re-dyed with N719 | 4.4 | 0.78 | 9.37 | 0.60 |
| M-F | Removal of ca. 80% N719 | 0.8 | 0.64 | 1.78 | 0.69 |
| M-G | Re-dyed with SQ1/5 mM | 2.0 | 0.66 | 5.34 | 0.58 |
| | CDCA | | | | |
| M-H | After desorption of all dyes | 0.3 | 0.56 | 0.80 | 0.65 |
| M-I | Re-dyed with N719 | 4.5 | 0.76 | 9.34 | 0.63 |
| M-J | Removal of ca. 60% N719 | 3.0 | 0.71 | 7.58 | 0.56 |
| M-K | Re-dyed with SQ1-HfSQ1 | 3.5 | 0.71 | 7.85 | 0.63 |
| | mix | | | | |
| M-L | Reverse cell | 1.2 | 0.68 | 2.42 | 0.75 |
| M-M | Removal of all dyes | 0.3 | 0.58 | 0.85 | 0.65 |
| M-N | Re-dyed with half SQ1 | 2.6 | 0.62 | 6.71 | 0.61 |
| M-O | Re-dyed with HfSQ1 then | 4.8 | 0.76 | 9.49 | 0.66 |
| | N719 | | | | |
| M-O- | Device O - reverse | 2.4 | 0.73 | 4.41 | 0.74 |
| Rev | illumination | | | | |

### Example 13

A TEC glass device was prepared with a P25 TiO₂ colloid sintered onto the photo-electrode and Pt sintered on to the counter electrode. The two electrodes were then sealed together with a Surlyn gasket and the device photo-electrode was then dyed with N719 solution (1 mM). The dye was partially desorbed using different concentration of tertiary-butyl ammonium hydroxide (4, 8, 20 or 40 mM). In between desorptions, the device cavity was rinsed as described previously before re-dyeing with a solution of N719. I-V data were measured after each dyeing and desorption step in reverse/normal illumination and on a black or a while background and the data are described in Table 14. These data show it is possible to control dye desorption using different concentrations of alkaline solution.

TABLE 14

| | | | | | | I_{sc} | |
|---|---|---|---|---|---|---|---|
| Device | | Illumination | Background | η % | V_{oc}/V | mA/cm² | FF |
| A | Dyed with N719 | Normal | Black | 4.7 | 0.81 | 9.94 | 0.58 |
| | | Reverse | Black | 2.9 | 0.74 | 6.27 | 0.62 |
| | | Normal | White | 4.9 | 0.8 | 12.05 | 0.51 |
| | | Reverse | White | 2.8 | 0.79 | 7.58 | 0.47 |
| A-Des | Desorbed by 40 mM | | | 0.3 | 0.59 | 0.81 | 0.68 |
| | TBN | | | | | | |
| B | Re-dyed with N719 | Normal | Black | 4.6 | 0.77 | 10.0 | 0.60 |
| | | Reverse | Black | 2.5 | 0.75 | 5.44 | 0.62 |
| | | Normal | White | 5.0 | 0.77 | 11.87 | 0.55 |
| | | Reverse | White | 5.0 | 0.77 | 11.87 | 0.55 |
| B-Des | Desorbed by 20 mM | | | 0.4 | 0.6 | 0.85 | 0.69 |
| | TBN | | | | | | |
| C | Re-dyed with N719 | Normal | Black | 4.7 | 0.77 | 10.23 | 0.60 |
| | | Reverse | Black | 3.0 | 0.75 | 5.95 | 0.68 |
| | | Normal | White | 4.9 | 0.77 | 11.30 | 0.57 |
| | | Reverse | White | 3.8 | 0.75 | 7.72 | 0.65 |
| C-Des | Desorbed by 8 mM | Normal | Black | 0.8 | 0.64 | 1.94 | 0.65 |
| | TBN | Reverse | Black | 0.4 | 0.64 | 0.88 | 0.64 |
| | | Normal | White | 0.9 | 0.64 | 2.21 | 0.64 |
| | | Reverse | White | 0.5 | 0.64 | 1.25 | 0.59 |
| D | Re-dyed with N719 | Normal | Black | 4.3 | 0.76 | 9.86 | 0.58 |
| | | Reverse | Black | 2.9 | 0.74 | 6.17 | 0.63 |
| | | Normal | White | 4.7 | 0.76 | 11.26 | 0.55 |
| | | Reverse | White | 3.8 | 0.75 | 8.14 | 0.62 |
| D-Des | Desorbed by 4 mM | Normal | Black | 1.3 | 0.66 | 2.73 | 0.72 |
| | TBN | Reverse | Black | 0.6 | 0.63 | 1.24 | 0.75 |
| | | Normal | White | 4.2 | 0.76 | 10.02 | 0.56 |
| | | Reverse | White | 2.8 | 0.74 | 5.87 | 0.64 |
| E | Re-dyed with N719 | Normal | Black | 4.6 | 0.76 | 11.64 | 0.52 |
| | | Reverse | Black | 3.2 | 0.75 | 6.24 | 0.69 |
| | | Normal | White | 4.9 | 0.77 | 10.35 | 0.61 |
| | | Reverse | White | 3.4 | 0.74 | 7.44 | 0.62 |

### Example 14

A TEC glass device was prepared with a P25 TiO₂ colloid sintered onto the photo-electrode and Pt sintered on to the counter electrode. The two electrodes were then sealed together with a Surlyn gasket and the device photo-electrode was then dyed with N719 solution. The dye was partially desorbed using different volumes of 4 mM tertiary-butyl ammonium hydroxide (100 to 1000 μl). In between desorptions, the device cavity was rinsed as described previously before re-dyeing with a solution of N719. I-V data were measured after each dyeing and desorption step in reverse/normal illumination and on a black or a white background and the data are described in Table 15. These data show it is possible to control dye desorption using different volumes of alkaline solution.

TABLE 15

| | | | | | | | Dye |
|---|---|---|---|---|---|---|---|
| Device, illumination and | | | | | I_{sc} | | desorbed |
| background | | | η % | V_{oc} /V | mA/cm² | FF | μg |
| Device A | Normal | Black | 4.4 | 0.77 | 9.17 | 0.63 | |
| (Dyed with | Reverse | Black | 2.7 | 0.75 | 5.09 | 0.71 | |
| N719) | Normal | White | 4.6 | 0.78 | 10.10 | 0.59 | |
| | Reverse | White | 3.8 | 0.76 | 7.58 | 0.65 | |
| Device B | Normal | Black | 0.9 | 0.66 | 1.806 | 0.73 | 132.0 |
| (N719 | Reverse | Black | 0.4 | 0.62 | 0.809 | 0.74 | |
| desorbed by | Normal | White | 1.0 | 0.66 | 2.148 | 0.72 | |
| 1000 μL TBN) | Reverse | White | 0.6 | 0.63 | 1.185 | 0.75 | |
| Device C | Normal | Black | 4.7 | 0.78 | 9.53 | 0.64 | |
| (Re-dyed with | Reverse | Black | 2.8 | 0.75 | 5.32 | 0.71 | |
| N719) | Normal | White | 5.4 | 0.79 | 11.21 | 0.61 | |
| | Reverse | White | 3.8 | 0.76 | 7.36 | 0.67 | |
| Device D | Normal | Black | 1.7 | 0.69 | 3.45 | 0.73 | 127.5 |
| (N719 | Reverse | Black | 0.8 | 0.65 | 1.67 | 0.76 | |
| desorbed by | Normal | White | 1.9 | 0.68 | 3.93 | 0.73 | |
| 750 μL TBN) | Reverse | White | 1.2 | 0.65 | 2.38 | 0.75 | |
| Device E | Normal | Black | 4.5 | 0.74 | 9.66 | 0.63 | |
| (Re-dyed with | Reverse | Black | 2.6 | 0.71 | 5.21 | 0.72 | |
| N719) | Normal | White | 5.1 | 0.74 | 11.22 | 0.61 | |
| | Reverse | White | 3.7 | 0.72 | 7.63 | 0.67 | |
| Device F | Normal | Black | 2.1 | 0.68 | 4.42 | 0.72 | 121.2 |
| (N719 | Reverse | Black | 1.2 | 0.66 | 2.33 | 0.75 | |
| desorbed by | Normal | White | 2.7 | 0.69 | 5.52 | 0.70 | |
| 500 μL TBN) | Reverse | White | 1.6 | 0.66 | 3.41 | 0.73 | |
| Device G | Normal | Black | 4.4 | 0.74 | 9.26 | 0.64 | |
| (Re-dyed with | Reverse | Black | 2.6 | 0.71 | 5.01 | 0.72 | |
| N719) | Normal | White | 4.9 | 0.75 | 10.79 | 0.61 | |
| | Reverse | White | 3.3 | 0.72 | 6.75 | 0.69 | |
| Device H | Normal | Black | 2.4 | 0.68 | 5.02 | 0.72 | 92.5 |
| (N719 | Reverse | Black | 1.3 | 0.66 | 2.63 | 0.75 | |
| desorbed by | Normal | White | 3.0 | 0.69 | 6.29 | 0.70 | |
| 250 μL TBN) | Reverse | White | 1.7 | 0.66 | 3.50 | 0.74 | |
| Device I | Normal | Black | 4.5 | 0.75 | 9.50 | 0.63 | |
| (Re-dyed with | Reverse | Black | 2.6 | 0.73 | 5.16 | 0.70 | |
| N719) | Normal | White | 4.8 | 0.74 | 11.09 | 0.59 | |
| | Reverse | White | 3.1 | 0.72 | 6.50 | 0.67 | |
| Device L | Normal | Black | 3.0 | 0.69 | 6.37 | 0.69 | 71.3 |
| (N719 | Reverse | Black | 1.6 | 0.67 | 3.25 | 0.74 | |
| desorbed by | Normal | White | 3.4 | 0.69 | 7.23 | 0.68 | |
| 100 μL TBN) | Reverse | White | 2.1 | 0.67 | 4.47 | 0.71 | |

### Example 15

A TEC glass device was prepared with a P25 TiO₂ colloid sintered onto the photo-electrode and Pt sintered on to the counter electrode. The two electrodes were then sealed together with a Surlyn gasket and the device photo-electrode was then dyed with N719 solution (1 mM) for different lengths of time. I-V data were measured after each dyeing time in reverse/normal illumination and on a black or a white background and the data are described in Table 16. These data show it is possible to control dye uptake using different dyeing times.

TABLE 16

| Dyeing | | | | | | |
|---|---|---|---|---|---|---|
| time | | | | | I_{sc} | |
| min | Illumination | Background | η % | V_{oc}/V | mA/cm² | FF |
| 1.0 | Normal | Black | 4.2 | 0.78 | 9.09 | 0.60 |
| | Reverse | Black | 3.0 | 0.77 | 5.78 | 0.67 |
| | Normal | White | 4.9 | 0.78 | 10.75 | 0.58 |
| | Reverse | White | 3.7 | 0.76 | 7.74 | 0.63 |
| 2.0 | Normal | Black | 4.3 | 0.79 | 10.75 | 0.50 |
| | Reverse | Black | 2.7 | 0.77 | 5.91 | 0.60 |
| | Normal | White | 4.5 | 0.79 | 11.71 | 0.49 |
| | Reverse | White | 3.5 | 0.78 | 7.74 | 0.58 |
| 3.0 | Normal | Black | 4.6 | 0.80 | 10.68 | 0.54 |
| | Reverse | Black | 3.0 | 0.78 | 6.07 | 0.64 |
| | Normal | White | 5.1 | 0.80 | 11.43 | 0.55 |
| | Reverse | White | 3.8 | 0.78 | 7.69 | 0.634 |
| 5.0 | Normal | Black | 4.7 | 0.80 | 10.50 | 0.55 |
| | Reverse | Black | 3.1 | 0.78 | 6.00 | 0.66 |
| | Normal | White | 5.0 | 0.80 | 12.04 | 0.52 |
| | Reverse | White | 3.9 | 0.78 | 8.25 | 0.61 |
| 6.0 | Normal | Black | 4.6 | 0.79 | 10.46 | 0.56 |
| | Reverse | Black | 3.01 | 0.77 | 6.02 | 0.66 |
| | Normal | White | 5.0 | 0.79 | 12.18 | 0.52 |
| | Reverse | White | 3.8 | 0.77 | 7.95 | 0.63 |
| 7.0 | Normal | Black | 4.7 | 0.79 | 10.41 | 0.57 |
| | Reverse | Black | 3.2 | 0.77 | 6.13 | 0.67 |
| | Normal | White | 5.1 | 0.79 | 11.73 | 0.55 |
| | Reverse | White | 3.8 | 0.78 | 7.70 | 0.63 |
| 9.0 | Normal | Black | 4.7 | 0.80 | 10.76 | 0.55 |
| | Reverse | Black | 3.1 | 0.78 | 6.17 | 0.65 |
| | Normal | White | 4.8 | 0.79 | 11.90 | 0.51 |
| | Reverse | White | 3.7 | 0.77 | 8.04 | 0.60 |
| 10.0 | Normal | Black | 4.5 | 0.79 | 10.96 | 0.51 |
| | Reverse | Black | 2.9 | 0.77 | 5.85 | 0.65 |
| | Normal | White | 4.7 | 0.79 | 11.97 | 0.50 |
| | Reverse | White | 3.4 | 0.77 | 7.42 | 0.60 |

### Example 16

A TEC glass device was prepared with a P25 TiO₂ colloid sintered onto the photo-electrode and Pt sintered on to the counter electrode. The two electrodes were then sealed together with a Surlyn gasket and the device photo-electrode was then dyed with N719 solution (1 mM). The dye was partially desorbed using tertiary-butyl ammonium hydroxide (4 mM) before adding D149 dye solution (0.5 mM). The N719 dye was then selectively removed using LiOH (200 μl, 100 mM) before re-dyeing with N719. In between desorptions, the device cavity was rinsed as described previously. I-V data were measured after each dyeing and desorption step in normal illumination on a black or a white background and the data are described in Table 17. These data show it is possible to selectively desorb one dye from a multiply dyed photo-electrode and then re-dye that electrode.

TABLE 17

| | | | | I_{sc}/mA | |
|---|---|---|---|---|---|
| Device | Background | η/% | V_{oc}/V | cm⁻² | FF |
| Dyed with N719 | Black | 4.9 | 0.81 | 10.36 | 0.59 |
| | White | 5.1 | 0.81 | 11.30 | 0.56 |
| Partial N719 removal by | Black | 3.4 | 0.76 | 7.01 | 0.63 |
| 50 μL TBN | White | 3.6 | 0.76 | 7.68 | 0.61 |
| Re-dyed with 250 μL | Black | 3.7 | 0.65 | 10.90 | 0.52 |
| D149 | White | 3.8 | 0.65 | 11.82 | 0.50 |
| Selective N719 desorbed | Black | 2.7 | 0.60 | 7.40 | 0.60 |
| by LiOH | White | 2.9 | 0.60 | 8.28 | 0.58 |
| Re-dyed with N719 | Black | 4.6 | 0.79 | 10.87 | 0.53 |
| | White | 4.9 | 0.80 | 11.73 | 0.53 |

### Example 17

A TEC glass device was prepared with two layers of DSL-18NRT TiO₂ colloid sintered onto the photo-electrode followed by a scattering layer and Pt sintered on to the counter electrode. The two electrodes were then sealed together with a Surlyn gasket and the device photo-electrode was then dyed with N719 solution. The dye was partially desorbed using tertiary-butyl ammonium hydroxide (4 mM) before adding SQ1 dye (10 μl, 0.68 mM with 5 mM CDCA). The N719 dye was then selectively removed using LiOH (100 mM) before the remaining SQ1 was re-dyed with N719. In between desorptions, the device cavity was rinsed as described previously. I-V data were measured after each dyeing and desorption step and the data are described in Table 18. These data show it is possible to selectively desorb one dye from a multiply dyed photo-electrode and then re-dye that electrode.

TABLE 18

| | | | | I_{sc} | |
|---|---|---|---|---|---|
| Device | | η % | V_{oc}/V | mA/cm² | FF |
| N-A | Dyed with N719 with CDCA | 5.9 | 0.77 | 13.96 | 0.55 |
| N-B | Partial N719 removal by | 5.3 | 0.74 | 11.74 | 0.61 |
| | 50 μL TBN | | | | |
| N-C | SQ1 added (10 μL) SQ1 | 5.3 | 0.73 | 12.01 | 0.60 |
| N-D | Selective N719 removal | 0.7 | 0.57 | 1.92 | 0.65 |
| | with LiOH | | | | |
| N-E | Remaining SQ1 re-dyed | 6.6 | 0.77 | 14.61 | 0.56 |
| | with N719 | | | | |
| N-E | One day later | 6.8 | 0.77 | 15.17 | 0.58 |

### Example 18

A TEC glass device was prepared with two layers of DSL-18NRT TiO₂ colloid sintered onto the photo-electrode followed by a scattering layer and Pt sintered on to the counter electrode. The two electrodes were then sealed together with a Surlyn gasket and the device photo-electrode was then dyed with D131 solution (2000 μl, 0.1 mM). The dye was partially desorbed using tertiary-butyl ammonium hydroxide (50 μl, 4 mM) before re-dyeing with D131 (2000 μl, 0.1 mM). After desorption, the device cavity was rinsed as described previously. I-V data were measured after each dyeing and desorption step and the data are described in Table 19. These data show it is possible to partially desorb the organic dye D131 and (hen to successfully re-dye the same electrode with the same dye.

TABLE 19

| Device | η % | V_{oc}/V | I_{sc}/mA/cm² | FF |
|---|---|---|---|---|
| Dyed with D131 | 5.1 | 0.68 | 11.79 | 0.61 |
| Partial D131 desorption | 2.5 | 0.60 | 6.29 | 0.63 |
| Re-dyed with D131 | 5.6 | 0.61 | 16.39 | 0.53 |

### Example 19

A TEC glass device was prepared with two layers of DSL-18NRT TiO₂ colloid sintered onto the photo-electrode followed by a scattering layer and Pt sintered on to the counter electrode. The two electrodes were then sealed together with a Surlyn gasket and the device photo-electrode was then dyed with N719 solution (2000 μl, 2 mM) containing chenodeoxycholic acid—CDCA (5 mM). The dye was partially desorbed using tertiary-butyl ammonium hydroxide (20 μl, 4 mM) before re-dyeing with a mixed solution (2000 μl) containing D131 (0.1 mM) and SQ1 (0.68 mM with 5 mM CDCA). The N719 dye was then selectively removed using LiOH solution (200 μl, 100 mM) before finally re-dyeing with N719 solution (1000 μl, 2 mM). After desorption, the device cavity was rinsed as described previously. I-V data were measured after each dyeing and desorption step and the data are described in Table 20. These data show it is possible to partially desorb N719 dye and then to re-dye with a mixed dye solution of D131 and SQ1, then to selectively desorb N719 from this electrode using LiOH and then re-dye that electrode resulting in increased short circuit current and open circuit voltage.

TABLE 20

| | | | I_{sc} | |
|---|---|---|---|---|
| Device | η % | V_{oc}/V | mA/cm² | FF |
| Dyed with N719 with CDCA | 6.5 | 0.77 | 15.02 | 0.56 |
| Partial N719 removal then add | 4.8 | 0.55 | 15.67 | 0.56 |
| 100 μL D131- SQ1 | | | | |
| Selective desorption of N719 with | 3.2 | 0.58 | 9.29 | 0.60 |
| LiOH | | | | |
| Re-dye N719 onto D131 + SQ1 | 6.3 | 0.76 | 14.34 | 0.58 |
| mixture | | | | |
| One day later | 6.3 | 0.77 | 15.30 | 0.53 |

### Example 20

A TEC glass device was prepared with two layers of DSL-18NRT TiO₂ colloid sintered onto the photo-electrode followed by a scattering layer and Pt sintered on to the counter electrode. The two electrodes were then sealed together with a Surlyn gasket and the device photo-electrode was then dyed with N719 solution (2000 μl, 1 mM) containing chenodeoxycholic acid—CDCA (5 mM). The dye was partially desorbed using tertiary-butyl ammonium hydroxide (10 μl, 4 mM) before re-dyeing with D149 solution (0.5 mM), The N719 dye was then selectively removed using LiOH solution (200 μl, 100 mM) before finally re-dyeing with N719 solution (2000 μl, 1 mM). After desorption, the device cavity was rinsed as described previously. I-V data were measured after each dyeing and desorption step and the data are described in Table 21. These data show that it is possible to partially desorb N719 dye and then to re-dye with the organic dye D149, then to selectively desorb N719 from this electrode using LiOH and then re-dye that electrode resulting in increased short circuit current and open circuit voltage.

TABLE 21

| | | | | | Isc | |
|---|---|---|---|---|---|---|
| Device | | Background | η % | V_{oc}/V | mA/cm² | FF |
| A | Dyed with N719 | Black | 6.0 | 0.77 | 12.46 | 0.57 |
| B | Partial removal | Black | 5.4 | 0.73 | 10.95 | 0.61 |
| | of N719 | White | 5.5 | 0.73 | 11.43 | 0.60 |
| C | Addition of | Black | 4.9 | 0.58 | 3.09 | 0.59 |
| | 100 μL | White | 5.0 | 0.57 | 13.73 | 0.58 |
| | of D149 | | | | | |
| D | Selective removal of | Black | 3.1 | 0.59 | 8.19 | 0.58 |
| | N719 | White | 3.2 | 0.58 | 9.10 | 0.55 |
| E | Re-dyed with N719 | Black | 6.5 | 0.74 | 13.05 | 0.61 |

### Example 21

### Example of Devices Prepared from Two Layers of DSL-18NRT Paste and a Scattering Layer Dyed and Re-Dyed with (1:1) Mixture of SQ1 and SQ2 Without CDCA

A TEC glass device was prepared with two layers of DSL-18NRT TiO₂ colloid sintered onto the photo-electrode followed by a scattering layer and Pt sintered on to the counter electrode. The two electrodes were then sealed together with, a Surlyn gasket and the device photo-electrode was then dyed with 1 ml of a (1:1) v/v mixed solution of SQ1 and SQ2 (1 ml of 0.34 mM SQ1 with 1 ml of 1.08 mM SQ2). The dye was then desorbed using tertiary-butyl ammonium hydroxide (1000 μl, 40 mM) before re-dyeing with the same SQ1:SQ2 solution. After dye desorption, the device cavity was rinsed as described previously. I-V data were measured after each dyeing and desorption step and the data are described in Table 22.

TABLE 22

| | Illumi- | | | | Isc | |
|---|---|---|---|---|---|---|
| Device | nation | Background | η % | V_{oc}/V | mA/cm² | FF |
| Dyed with | Normal | Back | 2.7 | 0.59 | 8.02 | 0.58 |
| 1:1 | | | | | | |
| mixt of SQ1 | Reverse | Black | 0.5 | 0.54 | 1.28 | 0.70 |
| and SQ2 | Normal | White | 2.9 | 0.59 | 8.44 | 0.58 |
| | Reverse | While | 0.9 | 0.55 | 2.48 | 0.68 |
| After | Normal | Black | 2.7 | 0.57 | 8.70 | 0.55 |
| desorption, | | | | | | |
| re-dyed with | Reverse | Black | 0.6 | 0.53 | 1.53 | 0.69 |
| SQ1:SQ2 mix | Normal | White | 2.9 | 0.57 | 9.16 | 0.56 |
| (1:1) | Reverse | White | 0.9 | 0.53 | 2.52 | 0.68 |

### Example 22

### Example of Devices Prepared from Two Layers of DSL-18NRT Paste and a Scattering Layer Dyed and Re-Dyed with (1:1) mixture of SQ1 and SQ2 with 10 mM CDCA

A TEC glass device was prepared with two layers of DSL-18NRT TiO₂ colloid sintered onto the photo-electrode followed by a scattering layer and Pt sintered on to the counter electrode. The two electrodes were then sealed together with a Surlyn gasket, and the device photo-electrode was then dyed with 1 ml of a (1:1) v/v mixed solution of SQ1 and SQ2 solution (1 ml of 0.34 mM of SQ1 and 1 ml of 1.08 mM SQ2) containing 10 mM CDCA. The dye was then desorbed using tertiary-butyl ammonium hydroxide (1000 μl, 40 mM) before re-dyeing with the same SQ1:SQ2 solution with 10 mM CDCA. After dye desorption, the device cavity was rinsed as described previously. I-V data were measured after each dyeing and desorption step and the data are described in Table 23.

TABLE 23

| | Illu- | Back- | | | Isc | |
|---|---|---|---|---|---|---|
| Device | mination | ground | η % | V_{oc}/V | mA/cm² | FF |
| Dyed with 1:1 | Normal | Black | 2.9 | 0.57 | 8.49 | 0.59 |
| mix of SQ1 and | Reverse | Black | 0.5 | 0.51 | 1.46 | 0.72 |
| SQ2 with CDCA | Normal | White | 3.0 | 0.57 | 9.35 | 0.57 |
| | Reverse | White | 1.0 | 0.53 | 2.65 | 0.68 |
| After desorption, | Normal | Black | 2.8 | 0.56 | 9.34 | 0.54 |
| re-dyed with | Reverse | Black | 0.7 | 0.52 | 2.00 | 0.69 |
| SQ1:SQ2 mix | Normal | White | 3.0 | 0.57 | 10.49 | 0.49 |
| (1:1) with CDCA | Reverse | White | 1.3 | 0.54 | 3.64 | 0.64 |

### Example 23

### Example of Devices Prepared from Two Layers of DSL-18NRT Paste and a Scattering Layer Dyed and Re-Dyed with (1:1) mixture of D131 and D149 Without CDCA

A TEC glass device was prepared with two layers of DSL-18NRT TiO₂ colloid sintered onto the photo-electrode followed by a scattering layer and Pt sintered on to the counter electrode. The two electrodes were then sealed together with a Surlyn gasket and the device photo-electrode was then dyed with a (1:1) v/v mixed solution of D131 and D149 (1 ml, 0.1 mM of D131 and 2 ml of 0.5 mM D149) without CDCA. The dye was then desorbed using tertiary-butyl ammonium hydroxide (1000 μl, 40 mM) before re-dyeing with the same D131:D149 solution without CDCA. After dye desorption. the device cavity was rinsed as described previously. I-V data were measured after each dyeing and desorption step and the data are described in Table 24.

TABLE 24

| | Illu- | | | | Isc | |
|---|---|---|---|---|---|---|
| Device | mination | Background | η % | V_{oc}/V | mA/cm² | FF |
| Dyed with | Normal | Black | 5.3 | 0.67 | 14.95 | 0.53 |
| D131:D149 | Reverse | Black | 1.3 | 0.61 | 2.88 | 0.72 |
| mix (1:1) | Normal | White | 5.3 | 0.67 | 16.08 | 0.49 |
| | Reverse | White | 1.3 | 0.62 | 4.41 | 0.67 |
| After | Normal | Black | 5.2 | 0.64 | 14.78 | 0.55 |
| desorption, | Reverse | Black | 1.0 | 0.57 | 2.62 | 0.69 |
| re-dyed with | Normal | White | 5.6 | 0.64 | 15.50 | 0.57 |
| D131:D149 | Reverse | White | 1.5 | 0.59 | 3.86 | 0.67 |
| mix (1:1) | | | | | | |

### Example 24

### Example of Devices Prepared from Two Layers of DSL-18NRT Paste and a Scattering Layer Dyed and Re-Dyed with (1:1) Mixture of D131 and D149 with 10 mM CDCA

A TEC glass device was prepared with two layers of DSL-18NRT TiO₂ colloid sintered onto the photo-electrode followed by a scattering layer and Pt sintered on to the counter electrode. The two electrodes were then sealed together with a Surlyn gasket and the device photo-electrode was then dyed with 2 ml of a (1:1) v/v mixed solution of D131 and D149 (1 ml, 0.1 mM of D131 and 1 ml of 0.5 mM D149) with 10 mM CDCA. The dye was then desorbed using tertiary-butyl ammonium hydroxide (1000 μl, 40 mM) before re-dyeing with the same D131:D149 solution with 10 mM CDCA. After dye desorption, the device cavity was rinsed as described previously. I-V data were measured after each dyeing and desorption step and the data are described in Table 25.

TABLE 25

| | Illu- | Back- | | | Isc | |
|---|---|---|---|---|---|---|
| Device | mination | ground | η % | V_{oc}/V | mA/cm² | FF |
| Dyed with | Normal | Black | 5.3 | 0.68 | 14.13 | 0.54 |
| D131:D149 | Reverse | Black | 2.0 | 0.64 | 4.22 | 0.72 |
| mixture with | Normal | White | 5.8 | 0.68 | 15.19 | 0.55 |
| CDCA | Reverse | White | 2.7 | 0.65 | 5.57 | 0.72 |
| After desorption, | Normal | Black | 5.2 | 0.68 | 12.48 | 0.60 |
| re-dyed with | Reverse | Black | 1.7 | 0.64 | 3.56 | 0.72 |
| D131:D149 | Normal | White | 5.3 | 0.69 | 13.05 | 0.58 |
| mixture with | Reverse | White | 2.4 | 0.65 | 5.20 | 0.69 |
| CDCA | | | | | | |

### Example 25

### Example of Devices Prepared from Two Layers of DSL-18NRT Paste and a Scattering Layer and Dyed, Desorbed and Re-Dyed with (1:1) Mixture of N719 and D149 with 10 mM CDCA

A TEC glass device was prepared with two layers of DSL-18NRT TiO₂ colloid sintered onto the photo-electrode followed by a scattering layer and Pt sintered on to the counter electrode. The two electrodes were then sealed together with a Surlyn gasket and the device photo-electrode was then dyed with 1 ml of a (1:1) v/v mixed solution of D149 and N719 (1 ml, 0.5 mM of D149 and 1 ml, 2 mM of N719) with 10 mM CDCA. The dye was then desorbed using tertiary-butyl ammonium hydroxide (1000 μl, 40 mM) before re-dyeing with the same D149:N719 solution with 10 mM CDCA. After dye desorption, the device cavity was rinsed as described previously. I-V data were measured after each dyeing and desorption step and the data are described in Table 28.

TABLE 26

| | | Back- | | | Isc | |
|---|---|---|---|---|---|---|
| Device | Illumination | ground | η % | V_{oc}/V | mA/cm² | FF |
| Dyed with | Normal | Black | 6.9 | 0.72 | 15.14 | 0.60 |
| N719:D149 | Reverse | Black | 1.8 | 0.66 | 3.51 | 0.73 |
| mixture (1:1) | Normal | White | 7.2 | 0.71 | 16.42 | 0.59 |
| | Reverse | White | 2.7 | 0.66 | 5.48 | 0.71 |
| After | Normal | Black | 6.8 | 0.71 | 15.30 | 0.60 |
| desorption, re- | Reverse | Black | 1.9 | 0.65 | 3.78 | 0.73 |
| dyed with | Normal | White | 6.6 | 0.72 | 15.33 | 0.57 |
| N719:D149 | Reverse | White | 2.6 | 0.67 | 5.19 | 0.71 |
| mixture (1:1) | | | | | | |

### Example 26

### Examples of Devices Showing Selective Removal of N719, SQ1 and D149 Dyes

Table 27 shows I-V DSC device testing data for the sequential ultra-fast sensitisation of several dyes. First, dyeing of SQ1 was achieved by pumping 300 μL of a 2.8 mM solution through the device cavity followed by an I⁻/I₃⁻ electrolyte leading to an efficiency of 2.3% (Device A). After electrolyte removal and rinsing with ethanol, 500 μl of 1 mM N719 solution was pumped through the cavity followed by an I⁻/I₃⁻ electrolyte increasing the efficiency to 4.5% (Device B) mainly through an increase in J_{sc} from 5.71 to 11.88 mA cm⁻² along with an increase in V_{oc} from 0.60 to 0.68V. After electrolyte removal and rinsing, 200 μl of 0.5 mM D149 solution was added giving another increase In efficiency to 5.7% through further increases in J_{sc} to 14.43 mA cm⁻² and V_{oc} to 0.70 V (Device C).

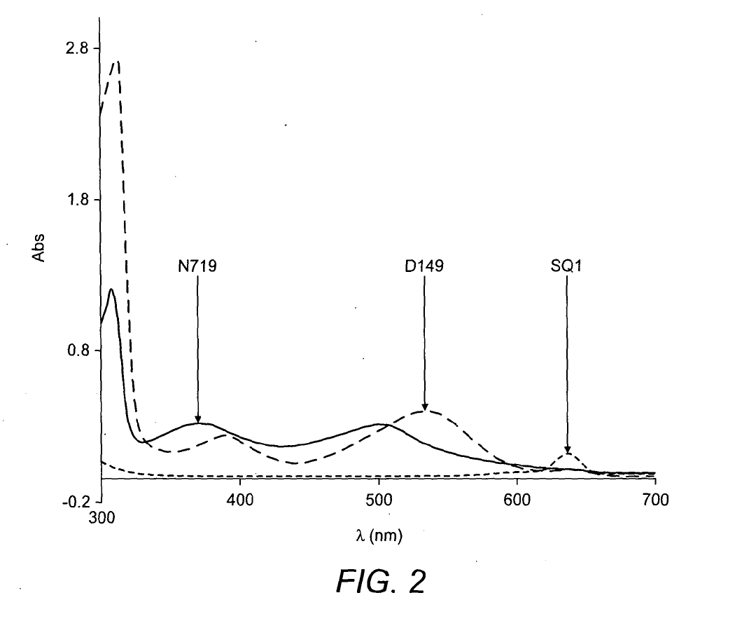

After electrolyte removal and rinsing, N719 was selectively desorbed by pumping 100 μl of 100 mM LiOH through the device cavity giving a solution containing only N719, as seen in FIG. 2, at a TiO₂ loading of 129.8 μg cm⁻². After re-filling with electrolyte, this showed a drop In device efficiency to 0.8% (Device D) mainly due to significantly a lower J_{sc} 1.38 mA cm⁻². The brown-blue colour of the photo-electrode confirmed that SQ1 and D149 loading remained. After electrolyte removal and rinsing, SQ1 was selectively desorbed using 100 μL of 1 mM Bu₄NOH giving a solution containing only SQ1, as seen in FIG. 2, at a TiO₂ loading of 1.8 μg cm⁻². After electrolyte re-filling, this led to a device efficiency of 1.2% (Device E) with J_{sc} increasing to 3.38 mA cm⁻² and V_{oc} dropping to 0.62 V. The red-brown colour of the device confirmed D149 loading remained. After electrolyte removal, D149 was desorbed by pumping 100 μl of 8 mM Bu₄NOH through the cell cavity followed by 100 μl acetone and then 100 μl ethanol to rinse the cavity leading to a solution containing only D149, as seen on FIG. 2, and a TiO₂ loading of 14 μg cm⁻².

TABLE 27

| Device | | η/% | V_{oc}/V | J_{sc}/mA cm⁻² | FF |
|---|---|---|---|---|---|
| A | 300 μl SQ1 | 2.1 | 0.60 | 5.71 | 0.61 |
| B | 500 μl N719 | 4.5 | 0.68 | 11.88 | 0.56 |
| C | 200 μl D149 | 5.5 | 0.69 | 13.36 | 0.59 |
| D | N719 desorbed | 0.8 | 0.79 | 1.38 | 0.68 |
| E | SQ1 desorbed | 1.2 | 0.62 | 3.38 | 0.57 |

1. A method for desorbing dye(s) from a finished dye sensitised solar cell (DSSC) and optionally re-dyeing said cell with the same or another or several dyes that comprises the steps of:
a. providing a sandwich cell structure comprising an electrode unit and a counter electrode unit, said electrode units being sealed together and comprising two holes drilled in the counter electrode;
b. sensitising the metal oxide photo-electrode by pumping a solution containing one or more dyes and/or a template molecule through the device cavity;
c. desensitising the DSSC of step b), either partially or completely, by pumping an alkaline solution between the sealed electrodes through one of the drilled holes and recovering the excess through the second hole, and wherein the alkaline solution has a pK_{b} ranging between −1 and 5 and wherein the reaction products of the dye and the alkaline solution reaction have a pH ranging between 8 and 14;
d. washing the desensitised cavity with solutions comprising either de-ionised water and/or an aqueous acid such a hydrochloric acid and/or organic solvents such as ethanol and/or acetone;
e. optionally pumping between the sealed electrodes, through one of the drilled holes in the counter-electrode, a new dye solution or a mixture of dyes in solution, said one or more dyes solution optionally comprising a template, said pumping being carried out at a rate adapted to the nature of the one or more dyes in solution;
f. optionally filling the re-dyed cell with fresh electrolyte;
g. optionally, recycling the removed one or more dyes;
h. repeating steps b) through f) as many times as desired with the same or with different dyes and/or templates.

2. The method of claim 1 wherein the desensitised solar cells are re-dyed and wherein steps e) and f) are present.

3. The method of claim 1 wherein the alkaline solution used in step c) is selected from amines, ammonium hydroxides or alkaline metal hydroxides and has a pK_{b} ranging between −1 and 5.

4. The method of claim 1, wherein the pK_{b}, the nature of the counter-ion and the concentration and volume of the base used along with the temperature and rate of pumping and the nature of the dye are selected to control the amount of dye removed.

5. The method of claim 1, wherein washing step d) is carried out with water, and/or acid, and/or organic solvent.

6. The method of claim 1, wherein the temperature of the process, the nature of the metal oxide, the dye solution solvents used, the rate of pumping of the dye solution through the device cavity and the nature and ratio of the different dye molecules, dye counterions and co-sorbents present within the dye solution are selected to control the rates of injection of the dyes and subsequent dye uptake.

7. The method of claim 1, wherein a template is added to the dye(s) solution.

8. The method of claim 7 wherein the template is selected from bulky, inert molecules which also have a linking group which can coordinate to the metal oxide surface.

9. The method of claim 8 wherein the linking group includes anionic or cationic compounds selected from carboxylates, phosphonates, sulfonates or amines.

10. The method of claim 8 wherein the template molecules include chenodeoxycholic acid, stearic acid, tertiary butyl pyridine, amino acids or guanadino carboxylic acids.

11. The method of claim 1, wherein the desorbed dyes are separated from the alkaline solution by neutralising any excess alkalinity with acid.

12. Dye-sensitised solar cells partially or totally desensitised and re-dyed with one or more dyes and characterised in that the amount and position of dyeing molecules is controlled by the multiple desensitising and re-dyeing method of claim 1.

13. A method of reducing incompatibility between dyes absorbing in different parts of the spectrum in a finished dye sensitised solar cell (DSSC), the method comprising the steps of:
a. providing a sandwich cell structure comprising an electrode unit and a counter electrode unit, said electrode units being sealed together and comprising two holes drilled in the counter electrode;
b. sensitising the metal oxide photo-electrode by pumping a solution containing one or more dyes and/or a template molecule through the device cavity;
c. desensitising the DSSC of step b), either partially or completely, by pumping an alkaline solution between the sealed electrodes through one of the drilled holes and recovering the excess through the second hole, and wherein the alkaline solution has a pK_{b} ranging between −1 and 5 and wherein the reaction products of the dye and the alkaline solution reaction have a pH ranging between 8 and 14;
d. washing the desensitised cavity with solutions comprising either de-ionised water and/or an aqueous acid such a hydrochloric acid and/or organic solvents such as ethanol and/or acetone;
e. optionally pumping between the sealed electrodes, through one of the drilled holes in the counter-electrode, a new dye solution or a mixture of dyes in solution, said one or more dyes solution optionally comprising a template, said pumping being carried out at a rate adapted to the nature of the one or more dyes in solution;
f. optionally filling the re-dyed cell with fresh electrolyte;
g. optionally, recycling the removed one or more dyes;
h. repeating steps b) through f) as many times as desired with the same or with different dyes and/or templates.

14. The method of claim 3, wherein the ammonium hydroxides include at least one of the following: a tetra-butyl ammonium hydroxide solution or an ammonium hydroxide solution.

15. The method of claim 3, wherein the alkaline metal hydroxides include lithium hydroxide.
